(19) United States
(12) Patent Application Publication
(10) Pub. No.: US 2006/0113631 A1
(43) Pub. Date: Jun. 1, 2006

(54) Structure of embedded capacitors and fabrication method thereof

(76) Inventors: Wei-Chun Yang, Taipei City (TW); Chien-Wei Chang, Yang-Mei Town (TW)

Correspondence Address: LIN & ASSOCIATES INTELLECTUAL PROPERTY, P.O. BOX 2339, SARATOGA, CA, 95070-0339, US

(21) Appl. No.: 10/998,076

(22) Filed: Nov. 26, 2004

(51) Int. Cl. H01L 29/00

(52) U.S. Cl. 257/532; 438/396; 438/398; 361/541

(57) ABSTRACT

A new structure is provided to replace the existing common planar capacitor structure used in printed circuit boards. The common planar capacitor structure utilizes a single dielectric layer and embedded capacitors with different capacitances are achieved by adjusting the sizes of the embedded capacitors' conductive terminals. Since general applications usually require capacitors whose capacitance range covers several orders of magnitude, these embedded capacitors have significant differences in terms of their conductive terminals' sizes. This will make the manufacturing process more complicated and difficult. The new structure combines inorganic material having a specific dielectric constant and polymer having another specific dielectric constant into a singulated coplanar capacitor structure.

### BACKGROUND OF THE INVENTION

1. Field of the Invention

The present invention relates to the printed circuit board, and in particular to the structure and fabrication method of embedded capacitors in the printed circuit board.

2. The Prior Arts

The printed circuit board with embedded passive elements, due to its size reduction and better electrical characteristics, has become a mainstream technology for printed circuit boards.

Currently, as shown in FIG. 1, the embedded capacitors of a printed circuit board are usually formed using a common planar capacitor structure. With this structure, the embedded capacitors are made of a dielectric layer 13 having a specific dielectric constant on a substrate 10. On the bottom and top of the dielectric layer 13, the conductive terminals 11 and 12 of the embedded capacitors are formed by copper foils lamination against the dielectric layer 13 and then etching the copper foils through a lithography process. The common planar capacitor structure is named as such because the embedded capacitors of the printed circuit board share the same planar dielectric layer.

The common planar capacitor structure has a number of disadvantages. First, as shown in FIG. 1, conducting wires 14 usually pass through the dielectric layer 13. Due to the RC time delay effect, printed circuit boards using this structure are not suitable for high frequency or high speed applications. Moreover, severe electromagnetic interference is inevitable as there is no grounding or shielding effect at the non-capacitor areas of the structure.

Secondly, as the common planar capacitor structure utilizes a single dielectric layer, embedded capacitors having different capacitances are achieved by varying the sizes of the embedded capacitors' conductive terminals. However, general applications usually require capacitors whose capacitance range covers several orders of magnitude. These embedded capacitors therefore have significant differences in terms of their conductive terminals' sizes. This will make the manufacturing process more complicated and difficult.

In addition, the common planar capacitor structure requires coating capacitive paste to cover the full panel. The coating of the expensive capacitive paste at places where no capacitor is required is an unnecessary waste.

Also, the lamination process for copper foil terminals would cause a significant variance in the dielectric layer's thickness.

### SUMMARY OF THE INVENTION

To overcome the foregoing disadvantages of common planar capacitor structure, the present invention adopts inorganic material having a specific dielectric constant and a polymer having another specific dielectric constant, and combines them in a singulated coplanar capacitor structure.

In this new structure, the embedded capacitors are formed by coating on the substrate a capacitive paste discretely or by laminating a dielectric sheet over the full panel and then etching the dielectric layer to form the capacitor pattern.

Traditional methods for forming the conductive terminals of the embedded capacitors such as the lamination of copper foils or using resin coated copper foils prepared in advance are not suitable for the new structure. The present invention therefore utilizes laser trimming or screen printing, along with various metallization processes, to form the upper conductive terminals of the embedded capacitors.

The present invention has the following advantages. First, the present invention has a better flexibility for routing and design than that of the common planar capacitor structure. The present invention also provides better signal integrity when used in high frequency and high speed electric circuits.

Secondly, as most embedded capacitors do not include reinforcement materials such as glass fibers and therefore there is a large variance in terms of the dielectric layer's thickness when fabricating RCC type of embedded capacitors using a lamination process, the present invention does not adopt the lamination process to avoid such variance.

Thirdly, as materials having different dielectric constants are used in the same layer of the new structure to achieve significantly different capacitances, the present invention requires less number of layers and thereby reduces manufacturing cost and increases the yield rate.

The foregoing and other objects, features, aspects and advantages of the present invention will become better understood from a careful reading of a detailed description provided herein below with appropriate reference to the accompanying drawings.

### BRIEF DESCRIPTION OF THE DRAWINGS

FIG. 1 is a sectional view of the common planar capacitor structure according to a prior art.

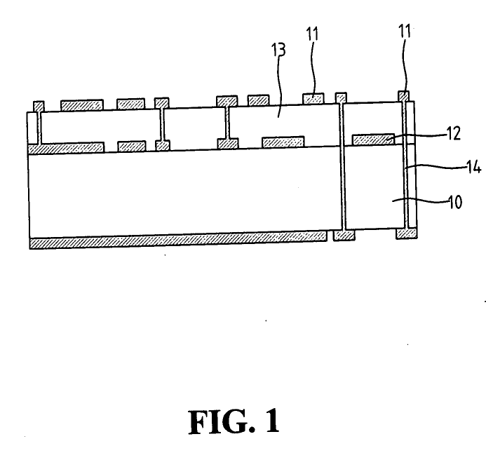

FIG. 2 is a sectional view of the singulated coplanar capacitor structure according the present invention.

### DETAILED DESCRIPTION OF THE PREFERRED EMBODIMENTS

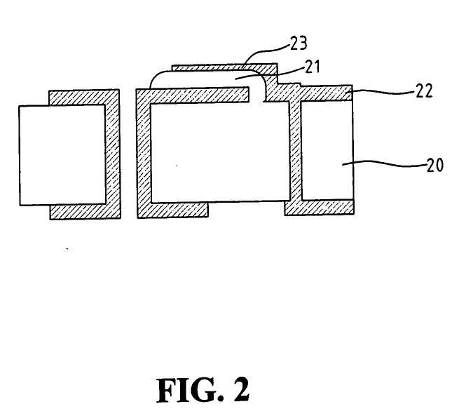

FIG. 2 is a sectional view of the singulated coplanar capacitor structure according the present invention. As shown in FIG. 2, a dielectric layer made of an inorganic material having a specific dielectric constant is coated or laminated on the substrate 20. Then a subtractive method such as wet etching, laser trimming, or plasma etching is applied to the dielectric layer to form a pattern 21. The pattern 21 can also be formed directly on the substrate 20 using an additive method such as screen printing and thin film deposition. The inorganic material can be a polymer thick film material, a metallic oxide, or a ceramic capacitor material.

At places where the dielectric layer is etched away, a polymer having a different dielectric constant is coated on the substrate 20 to form a second pattern 22. The two patterns 21 and 22 jointly form a singulated coplanar structure. The polymer can be a polymer capacitive paste.

Then, on top of the two patterns, upper conductive terminals 23 are formed through the following two steps. The top surfaces of the patterns 21 and 22 are first put through a roughening process. Then the roughened surfaces are metalized to form the upper conductive terminals 23.

Subsequently, the other layers of the printed circuit board can be developed with traditional procedures.

The present invention also provides a method for forming embedded capacitors with the aforementioned new structure. The method consists of the following steps. First, a substrate is provided. A dielectric layer made of an inorganic material having a specific dielectric constant is then coated on the substrate. The dielectric layer is processed using wet etching, laser trimming, or plasma etching to form a pattern. Then, at places over the substrate where the dielectric layer is etched away, a polymer having another specific dielectric constant is deposited using screen printing or thin film deposition to form a second pattern. Upper conductive terminals of the embedded capacitors are then formed on top of the patterns.

Forming the upper conductive terminals involves a two-step process. First, the top surfaces of the patterns are put through a roughening process. The roughening process can be performed using traditional dismear process, such as potassium permanganate solution or within a vacuum plasma environment. Then the roughened surfaces are metalized to form the upper conductive terminals using chemical copper, copper plating, or vacuum sputtering.

Compared with the common planar capacitor structure, the present invention has the following advantages.

The singulated structure of the present invention greatly increases the design flexibility of the printed circuit board. The signal integrity of the printed circuit board is also highly enhanced.

Embedded capacitors with a wide range of capacitances covering several orders of magnitude can be achieved all within a single layer of the printed circuit board. As no additional dielectric layer is required, the production cost is lower and the yield rate is better.

The metallization process adopted by the present invention has a better processing accuracy and selectiveness than those of subtractive methods using copper lamination and etching.

Although the present invention has been described with reference to the preferred embodiments, it will be understood that the invention is not limited to the details described thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. A structure of embedded capacitors, comprising:
a substrate;
a first pattern having a first dielectric constant located over said substrate;
a second pattern having a second dielectric constant located over said substrate coplanar but not overlapping with said first pattern; and
a plurality of conductive terminals located over said first and second patterns formed by metalizing top surfaces of said first and second patterns.

2. The structure of embedded capacitors according to claim 1, wherein said first pattern is formed by depositing a dielectric layer and then etching said dielectric layer by a subtractive method selected from the group consisting of wet etching, laser trimming, and plasma etching.

3. The structure of embedded capacitors according to claim 1, wherein said first pattern is formed directly on said substrate by an additive method selected from the group consisting of screen printing and thin film deposition.

4. The structure of embedded capacitors according to claim 1, wherein said first pattern is made of a material selected from the group consisting of a polymer thick film material, a metallic oxide, or a ceramic capacitor material.

5. The structure of embedded capacitors according to claim 1, wherein said second pattern is made of a polymer capacitive paste.

6. The structure of embedded capacitors according to claim 1, wherein said second pattern is formed by using an additive method selected from the group consisting of screen printing and thin film deposition.

7. A method for fabricating embedded capacitors, comprising the steps of:
providing a substrate;
coating a dielectric layer made of a first material having a first dielectric constant on said substrate;
forming a first pattern out of said dielectric layer;
depositing a second dielectric material having a second dielectric constant different from said first dielectric constant on places of said substrate where said first pattern is not present and forming a second pattern coplanar with said first pattern; and
forming upper conductive terminals on said first and second patterns.

8. The method for fabricating embedded capacitors according to claim 7, wherein said first pattern is formed using a subtractive method selected from the group consisting of wet etching, laser trimming, and plasma etching.

9. The method for fabricating embedded capacitors according to claim 7, wherein said second material is a polymer capacitive paste.

10. The method for fabricating embedded capacitors according to claim 7, wherein said second pattern is formed using an additive method selected from the group consisting of screen printing and thin film deposition.

11. The method for fabricating embedded capacitors according to claim 7, wherein said upper conductive terminals are formed by applying a metallization process on upper surfaces of said first and second patterns.

12. The method for fabricating embedded capacitors according to claim 11, wherein said metallization process further comprises the steps of:
performing a roughening process on upper surfaces of said first and second patterns; and
performing a surface metallization process on roughened upper surfaces of said first and second patterns.

13. The method for fabricating embedded capacitors according to claim 12, wherein said roughening process is performed through a method selected from the group consisting of the use of a permanganate solution and the use of a vacuum plasma environment.

14. The method for fabricating embedded capacitors according to claim 12, wherein said surface metallization process is performed through a method selected the group consisting of the use of chemical copper, copper plating, and vacuum sputtering.
